(19) United States
(12) Patent Application Publication
(10) Pub. No.: US 2024/0319621 A1
(43) Pub. Date: Sep. 26, 2024

(54) APPARATUS AND METHOD FOR AVOIDING A DEGRADATION OF AN OPTICAL USED SURFACE OF A MIRROR MODULE, PROJECTION SYSTEM, ILLUMINATION SYSTEM AND PROJECTION EXPOSURE APPARATUS

(71) Applicant: Carl Zeiss SMT GmbH, Oberkochen (DE)

(72) Inventors: Moritz BECKER, Aalen (DE); Arnoldus Jan STORM, Delft (NL); Julian KALLER, Koenigsbronn (DE)

(21) Appl. No.: 18/732,005

(22) Filed: Jun. 3, 2024

Related U.S. Application Data
(63) Continuation of application No. PCT/EP2022/082902, filed on Nov. 23, 2022.

(30) Foreign Application Priority Data
Dec. 15, 2021 (DE) 10 2021 214 366.0

(51) Int. Cl. G03F 7/00

(52) U.S. Cl. CPC G03F 7/70891; G03F 7/7085; G03F 7/70933

(57) ABSTRACT

Mirror module for a projection exposure apparatus that includes an optical used surface, an optical measurement surface, a measurement apparatus for determining the degradation state of the measurement surface, characterized in that: the mirror module comprises a temperature control apparatus configured such that the temperature of the optical measurement surface is lower than the temperature of the optical used surface.

### CROSS-REFERENCE TO RELATED APPLICATION

This is a Continuation of International Application PCT/EP2022/082902, which has an international filing date of Nov. 23, 2022, and the disclosure of which is incorporated in its entirety into the present Continuation by reference. This Continuation also claims foreign priority under 35 U.S.C. § 119(a)-(d) to and also incorporates by reference, in their entirety, German Patent Application DE 10 2021 214 366.0 filed on Dec. 15, 2021.

### FIELD

The disclosed techniques relate to a mirror module for a projection exposure apparatus, to an illumination system with such a mirror module, to a projection lens with such a mirror module, and to a projection exposure apparatus with such an illumination system and/or such a projection lens. The disclosed techniques further relate to a method for avoiding a degradation of an optical used surface of a mirror module for a projection exposure apparatus.

### BACKGROUND

Projection exposure apparatuses for semiconductor lithography serve to produce microstructured components via a photolithographic method. In this case, a structure-bearing mask, the so-called reticle, is imaged onto a photosensitive layer with the aid of a projection optical unit or a projection system. The minimum structure size that can be imaged with the aid of such a projection optical unit is determined by, among other things, the wavelength of the imaging light used. The shorter the wavelength of the imaging light used, the smaller the structures that can be imaged with the aid of the projection optical unit. Nowadays, imaging light of the wavelength of 193 nm or imaging light of a wavelength in the extreme ultraviolet range (EUV), i.e., at least 5 nm and at most 30 nm, is used. When using imaging light of a wavelength of 193 nm, both refractive optical elements and reflective optical elements are used within the projection exposure apparatus. When using imaging light of a wavelength in the EUV range, exclusively reflective optical elements, in particular mirrors as integral parts of mirror modules, are used, which are typically operated under vacuum conditions in a vacuum environment.

Such mirror modules typically have optical elements with a reflective surface due to a reflective coating arranged on a substrate of the optical element. If the wavelength of the imaging light used is in the EUV range, the reflective coating typically comprises a plurality of individual layers constructed alternately of materials having different refractive indices. Such a multilayer system can comprise alternating silicon and molybdenum layers, for example. During the operation of the projection exposure apparatus, the reflective coating is exposed to EUV radiation that fosters a chemical reaction between the layer materials used and gaseous substances present in a residual gas atmosphere in an interior of the mirror module, in particular within the projection exposure apparatus. This process causes degradation in the layer materials used, which leads to a reduction in the layer reflection and consequently impairs the transmission of the overall system.

In order to protect the individual layers against degradation, a capping layer is typically applied on the reflective coating. Such a capping layer can comprise or consist of, for example, ruthenium. Regarding one possible construction of the capping layer, reference is made to U.S. Ser. No. 10/061,204 B2. Such a capping layer may also be subject to a degradation, for example an oxidation, as a result of a chemical reaction with residual gas present in the vacuum environment, wherein the chemical reaction is initiated or at least fostered by the EUV radiation. This degradation of the capping layer during the operation of the projection exposure apparatus may lead to an undesired reduction in a reflectivity of the respective optical element within the mirror module and consequently to a reduction in the transmission of the mirror module.

Regarding the construction of optical elements in a projection exposure apparatus, reference is made to U.S. Pat. No. 9,632,436 B2, EP 1927032 B1 and DE 102018123328 A1.

Additionally, EP 1901125 A1 describes the use of at least one optical surface of a test element in an immediate environment of a reflective optical element arranged in a beam path that is an integral part of an optical system. In this case, the optical surface of the test element has a reflective optical coating comparable to the reflective optical element and is operated in comparable conditions owing to the immediate vicinity to said element. The same conditions are understood to mean, for example, the residual vacuum and the beam intensity. In this way, changes in the reflective optical element can be described by a change in the optical surface of the test element. However, this procedure means that the same risk of degradation exists for the surfaces of both elements.

DE 102019219024 describes a method and an apparatus for avoiding a degradation of an optical used surface of a mirror module by determining a degradation value at different times during operation. Based on this, a progression of the degradation can be estimated and a comparison with a threshold degradation value is possible, which in turn forms the basis for specific countermeasures. The degradation value is determined with the aid of optical methods, for example the determination of a reflectivity value, a polarization value or a phase value. Even in this procedure for determining a degradation, the optical used surface is subject to an increased risk of actual degradation.

Against the aforementioned background, it is an object of the techniques disclosed herein to provide a mirror module for a projection exposure apparatus in which the risk of a degradation of the optical used surface during operation is determined early and the degradation can thus be effectively avoided.

### SUMMARY

It is an object of the techniques disclosed herein to provide a method for avoiding a degradation of an optical used surface of a mirror module for a projection exposure apparatus.

This object is achieved by a mirror module comprising an optical used surface, an optical measurement surface and a measurement apparatus. An optical used surface as is used in the present disclosure is understood by the skilled artisan to mean a reflective optical surface that makes imaging light after reflection usable for further use. An optical measurement surface, on the other hand, is understood by the skilled artisan to mean a reflective optical surface that is identical to the optical used surface but cannot make imaging light after reflection usable for further use. Rather, the optical used surface is describable by the optical measurement surface. The measurement apparatus here serves for determining a degradation state of the measurement surface. The mirror module furthermore comprises a temperature control apparatus, which is configured such that the temperature of the measurement surface is lower than the temperature of the optical used surface. A temperature control apparatus within the meaning of this application is understood to mean an active apparatus for selectively setting a temperature of the optical measurement surface and/or optical used surface and/or a passive apparatus for the preferred setting of a temperature difference between the optical measurement surface and the optical used surface. For selectively setting the temperature(s), the temperature control apparatus, as an active apparatus, can include a plurality of units, the temperature control units. When setting the temperature of the optical measurement surface and/or optical used surface, a temperature distribution over the respective surface may also come about. In this case, the lower temperature of the optical measurement surface refers to the maximum temperature of the optical used surface. The difference in temperatures between the two optical surfaces fosters adsorption of the oxidizing species causing the degradation on the optical measurement surface in comparison with the optical used surface. The degradation on the optical measurement surface that is possible as a result is detectable by the measurement apparatus before a degradation of the optical used surface begins.

In one embodiment, the optical used surface and the optical measurement surface have the same reflective coating. In this way, a degradation of the optical used surface can be described by way of the optical measurement surface. In a further embodiment, the optical used surface and the optical measurement surface are arranged next to each other. With this arrangement in the immediate vicinity, the optical used surface and the optical measurement surface are operated under comparable conditions, such as the composition of the residual gas atmosphere and the power of the EUV radiation. In a further embodiment, the optical used surface and the optical measurement surface can be arranged together on one optical element. This arrangement makes it possible to dispense with additional infrastructure, for example for a further optical element, which is advantageous in regions of little installation space in the mirror module.

In one embodiment, the temperature control apparatus is configured such that the temperature of the measurement surface is at least 0.5 K, preferably 1 K, with particular preference 2 K, lower than the temperature of the optical used surface. This difference in temperature leads to increased adsorption of the oxidizing species, such as water or carbon dioxide, on the optical measurement surface compared with the optical used surface.

According to a further embodiment, the mirror module comprises at least one first optical element with the optical used surface and at least one second optical element with the optical measurement surface. Such a division simplifies control of the different temperatures of the optical used surface and the optical measurement surface.

Owing to the division of the optical used surface on the at least one first optical element and the optical measurement surface on the at least one second optical element, it is possible to arrange both optical elements within the mirror module so that they are spatially separated from each other. The spatial separation makes it possible to, for example, place the optical measurement surface in a non-usable region of the beam path within the mirror module. Since the reflected light from the optical measurement surface cannot be made usable for further use, the absolute proportion of the optical used surface can thus be increased.

According to a further embodiment, the separate arrangement of the measurement surface on the second optical element enables the second optical element to be exchanged. If the measurement surface on the second optical element has degraded, it can be replaced by exchanging the second optical element with an intact measurement surface.

A further embodiment of the first optical element of the type that includes a plurality of used facets is particularly advantageous with respect to the imaging properties of the mirror module. Owing to the used facets, the mirror module becomes an integral part of a faceted illumination system, in particular of a reflective fly's eye condenser.

According to a further embodiment, the second optical element a plurality of measurement facets. With the segmentation of the measurement surface of the mirror module achieved in this way, different spatially separate regions of the optical used surface of the first optical element are addressable in each case by individual measurement facets. For example, it is possible hereby to describe the influence of the power of the EUV radiation which spatially varies on the optical used surface, within the mirror module. Likewise, individual measurement facets can also be selectively subjected to a different power of the EUV radiation in each case, with the different powers corresponding to a region of a power distribution on the optical used surface. The measurement apparatus for determining the degradation state of the measurement surface for this purpose switches accordingly between the individual measurement facets. Likewise, the various measurement facets enable continued monitoring of the optical used surface of the mirror module if a measurement facet fails as a consequence of degradation.

According to a further embodiment, the individual measurement facets are configured such that each measurement facet is assigned a separate measurement apparatus. In this way, it is possible to simultaneously describe within the mirror module spatially separate regions, in particular regions of the optical used surface, by way of respective individual measurement facets with associated measurement apparatuses.

According to one embodiment, the described measurement apparatuses are configured here such that they determine the degradation state on the basis of a reflectivity value, a phase value or a polarization value. Using these optical measurement methods for the measurement surface, the measurement may be performed contactlessly. In this case, a measurement infrastructure, such as for example a measurement light source for measurement light and a detector, is located spatially separated from the optical measurement surface within and/or outside of the mirror module. In particular, the measurement infrastructure is located outside the beam path. The optical measurement methods described here exhibit high sensitivity to a beginning and progressing degradation of the optical measurement surface. In this way, even reversible processes on the measurement surface are describable, and so there is the possibility of adapting operating conditions that foster a beginning degradation. Degradation of the optical measurement surface and in particular of the optical used surface within the mirror module is thus counteracted.

According to one embodiment, the temperature control apparatus of the mirror module comprises at least one first temperature control unit for setting a first temperature T1 of the measurement surface. The active temperature control of the optical measurement surface allows the temperature thereof to be set, in particular set lower, compared with a temperature of the optical used surface. In this way, a temperature gradient that fosters the preferred adsorption of the oxidizing species on the optical measurement surface is achievable.

According to a further embodiment, the first temperature control unit is designed to set different temperatures T1 on different measurement facets. In this way it is possible to selectively set different temperature gradients for measurement facets to which different power of the EUV radiation is applied with respect to the optical used surface. If the power of the EUV radiation or its distribution on the optical used surface is known, different sensitivities can be set by way of the differently set temperatures T1 on measurement facets to which EUV radiation is applied in each case comparably with the optical used surface. For regions with a higher output, for example a greater temperature gradient may be advantageous because in this way a beginning degradation of the optical measurement surface is indicated earlier. This is advantageous because, owing to the greater power of the EUV radiation, a faster transfer of the degradation to the optical used surface must be expected.

According to a further embodiment, the temperature control apparatus of the mirror module comprises at least one second temperature control unit for setting a second temperature T2 of the optical used surface. The active temperature control of the optical used surface allows the temperature T2 thereof to be set, in particular set higher, in comparison with the temperature T1 of the optical measurement surface. In this way, a temperature gradient that fosters the preferred adsorption of the oxidizing species on the optical measurement surface is likewise achievable. If the temperature control apparatus comprises the first and second temperature control units, the temperatures T1 of the optical measurement surface and also T2 of the optical used surface are settable. In this way, the gradient between the two optical surfaces is advantageously controllable.

In this case, the first and/or second temperature control unit of the mirror module is designed for example as a fluid heater, Peltier element, radiant heater or electrical resistance heater.

Being designed as a fluid heater has the advantage here that greater quantities of heat are able to be supplied or dissipated. The heat-carrying medium is guided here encapsulated within the mirror module, which is advantageous on account of the high requirements relating to cleanliness within a mirror module of a projection exposure apparatus.

A design of the first and/or second temperature control units as a Peltier element likewise allows an increase and/or reduction in the temperatures T1 and T2. Particularly low temperatures are settable by Peltier elements. Peltier elements are furthermore characterized by a small size and low weight and do not require a heat-carrying medium. With an appropriate arrangement, Peltier elements are likewise placeable on the optical elements encapsulated by the optical surfaces within the mirror module.

A design of the first and/or second temperature control units as a radiant heater or an electrical resistance heater allows the selective increase in the temperatures T1 and/or T2. The temperature in this case is settable directly by the use of radiant heaters and locally on the surface. Electrical resistance heaters are likewise arrangeable on the optical elements encapsulated by the optical surfaces within the mirror module.

According to a further embodiment, the temperature control apparatus is configured for passively setting a temperature T1 of the optical measurement surface differently, in particular lower, compared with a temperature T2 of the optical used surface owing to different heat capacities of the first optical element and of the second optical element. Owing to a greater heat capacity, a smaller increase in the temperature is achieved with a comparable thermal load, for example during operation. In this way, preferred temperature gradients can be set during operation between different regions, in particular between the first and the second optical element, in a manner such that the second optical element with a greater heat capacity develops a temperature T1 that is lower in comparison with T2. This embodiment acts particularly advantageously due to a supporting effect, in particular in combination with active temperature control. Different heat capacities of the optical elements can be achieved for example by way of different substrate materials or by way of a different extent of the binding or coupling of the optical elements to a carrier. The extent or the coupling of an optical element to a carrier here defines the possibility of dissipating heat thereby.

The illumination system according to the disclosed techniques for a projection exposure apparatus is characterized by a particularly high intensity because it is located in the beam path following the source. Local intensity peaks by way of specific illumination settings are likewise possible in the illumination system. The use of such a mirror module monitoring the degradation is therefore advantageous.

For the projection lens according to the disclosed techniques for a projection exposure apparatus, degradation disturbances have a particularly harmful effect on the imaging properties, and the use of such a mirror module monitoring the degradation as an integral part of the projection lens is therefore advantageous.

The projection exposure apparatus according to the disclosed techniques is characterized by the illumination system according to the disclosed techniques and/or the projection lens according to the disclosed techniques. The advantages already mentioned are evident therefrom. Further advantages and preferred features are evident from the description above and from the claims.

In a method of the disclosed techniques for avoiding the degradation of the optical used surface of the mirror module of a projection exposure apparatus, a degradation value of the optical measurement surface of the mirror module is determined and a temperature difference between the optical measurement surface and the optical used surface is set such that the temperature of the optical measurement surface is lower than the temperature of the optical used surface.

Since the lower temperature of the optical measurement surface fosters the adsorption of oxidizing species and other contaminants on the optical measurement surface, this adsorption is consequently more pronounced on the optical measurement surface compared with the optical used surface. Under the largely identical ambient conditions between the two optical surfaces, degradation is consequently fostered on the optical measurement surface because the surface concentration of oxidizing species required therefore is increased. If the determination of the degradation value of the optical measurement surface indicates a beginning degradation, this process is suppressed for the optical used surface due to the temperature being higher than for the optical measurement surface. Using this method, monitoring a degradation of an optical used surface is provided thereby, without such a degradation taking place thereon or impairing the imaging properties of the mirror module.

In this method, at least a temperature difference of 0.5 K, preferably 1 K, with particular preference 2 K, is set. This difference in temperature is useful for a sufficiently increased adsorption of the oxidizing species, such as water or carbon dioxide, to take place on the optical measurement surface compared with the optical used surface. As a result, a corresponding protection of the optical used surface is ensured because the fostering of the degradation of the optical measurement surface also manifests in a correspondingly large temporal offset.

If the determined degradation value changes in the direction of a limit degradation value (also referred to herein as a threshold degradation value) and reaches it, at least one measure for reducing the degradation is initiated. The limit degradation value is selected here such that the underlying degradation of the measurement surface is reversible. For example, the limit degradation value is achieved when increased adsorption of contaminants and/or oxidizing species occurs but no reaction.

The various measures will be briefly explained below. They can be applied individually or in combination.

As a first measure of reducing the degradation according to the disclosed techniques, the temperature T1 of the optical measurement surface and/or T2 of the optical used surface is increased. This reduces the concentrations of potential contaminants and/or oxidizing species on the respective surfaces.

As a second measure of reducing the degradation according to the disclosed techniques, the purge gas atmosphere is modified. As described in DE 102009029121 A1, the projection exposure apparatus is operated in an atmosphere of partially activated hydrogen in the region of the optical surfaces. One example possibility of counteracting the degradation, therefore, includes increasing the flow of the hydrogen purge gas. It is likewise possible to increase the proportion of activated hydrogen.

As a third measure of reducing the degradation according to the disclosed techniques, the power of the EUV radiation used for imaging is partially or completely reduced. The power of the EUV radiation used determines the proportion of radical and charged species within the mirror module, in particular in the region of the optical used surface, due to the formation of a beam-induced plasma. The speed of the degradation of the optical used surface and the optical measurement surface is determined by the proportion of oxidizing species of this plasma. A reduction in the power of the EUV radiation therefore reduces this proportion and thereby slows down the effect of the degradation.

As a fourth measure, a reduction of one or more concentrations of oxidizing species is performed. In particular, this relates to the partial pressures of oxidizing species such as water, oxygen or carbon dioxide in the residual gas atmosphere. It is known that these partial pressures and the beam intensity influence the process of degradation such that an increase in the partial pressures or in the concentration of the oxidizing species in the residual gas atmosphere accelerate said process. For this purpose, the concentration of the oxidizing species is monitored even before operation begins, and being below an upper limit concentration of the projection exposure apparatus is defined as a condition for starting operation.

### BRIEF DESCRIPTION OF THE DRAWINGS

The accompanying drawings show purely schematically, and not to scale, in:

FIG. 1 a sectional illustration of a mirror module of a projection exposure apparatus within a separated vacuum environment, including a temperature-controllable optical used surface on a first optical element, a temperature-controllable optical measurement surface on a second optical element, and a measurement apparatus for determining the degradation state of the optical measurement surface;

FIG. 2 a sectional illustration of an EUV projection exposure apparatus including the source unit, an illumination system, a projection optical unit, individual mirror modules and partially their separated vacuum environment;

FIG. 3 an exemplary plan view of a first optical element with an optical used surface that includes a plurality of used facets, an exchangeable second optical element, separated from the first optical element, with a measurement surface in the form of an individual facet, and a measurement apparatus for determining a degradation value of the optical measurement surface;

FIG. 4 an exemplary plan view of an optical element that includes a plurality of used facets with an optical used surface, a plurality of measurement facets with an optical measurement surface, and a plurality of measurement apparatuses for determining a degradation value of the optical measurement surface, with each measurement facet being assigned a separate measurement apparatus;

FIG. 5 a flow chart for carrying out a method for avoiding a degradation of an optical used surface of a mirror module of a projection exposure apparatus; and

FIG. 6 a possible profile of a degradation value of an optical measurement surface of a mirror module of a projection exposure apparatus as a function of the operating duration.

### DETAILED DESCRIPTION

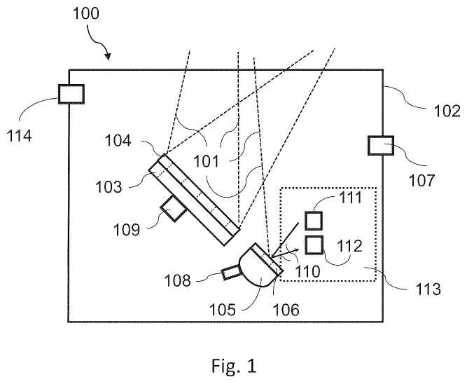

According to one exemplary embodiment, FIG. 1 shows a mirror module 100 for reflecting imaging radiation 101, in particular EUV radiation. By way of example, the radiation can be made available by reflection at an optical element (not illustrated here) connected upstream in the beam path. Here, the radiation 101 enters a vacuum housing 102, which surrounds a first optical element 103. A vacuum unit for evacuating the interior space of the vacuum housing 102 is not illustrated. The radiation 101 is then reflected at an optical used surface 104 of the first optical element 103 and exits the vacuum housing 102. For example, the radiation 101 can then travel to a subsequent optical element (not illustrated) positioned outside the vacuum housing 102. A second optical element 105 with an optical measurement surface 106 is located in an immediate vicinity of the first optical element 103, likewise within the vacuum housing 102. For determining the residual gas atmosphere of the interior space within the vacuum housing 102, a residual gas analyser 107 is located at the vacuum housing 102. For example, the concentrations of the oxidizing species within the vacuum housing 102 can in this way be detected by the residual gas analyser 107.

The temperature of the second optical element 105 can be controlled to a specifiable temperature T1 by a first temperature control unit 108 of a temperature control apparatus. The temperature of the first optical element 103 can be controlled to a specifiable temperature T2 by a second temperature control unit 109. T1 differs here from T2. For use according to the disclosed techniques, it is advantageous if T1 is lower than T2. The temperature control units 108 for the temperature control of the second optical element 105 and 109 for the temperature control of the first optical element 103 can therefore have different designs, and their positioning in FIG. 1 is only an example. By way of example, the temperature control units can achieve media-based temperature control of the two optical elements using a fluid. This is realized by guiding a fluid that has been conditioned to a settable temperature through the optical element via an inlet and an outlet. In a further embodiment, the temperature control units are designed as Peltier elements. In a further embodiment, the temperature control units 108 and 109 are designed as radiant heaters in accordance with DE 102017207862 A1. In this case, the temperature control units 108 and 109 can act directly onto the optical measurement surface 106 of the second optical element 105 and onto the optical used surface 104 of the first optical element 103, thereby achieving local temperature control on both optical surfaces. In a further advantageous embodiment, the temperature control is implemented via electrical heating elements. Likewise, the first optical element 103 can have a different, in particular lower, heat capacity than the second optical element 105. In this way, with a comparable introduction of heat, a temperature T1 of the second optical element 105 is established, which differs from, in particular is lower than, a temperature T2 of the first optical element 103.

A further function of the mirror module illustrated in FIG. 1 is provided by the determination of a degradation value of the optical measurement surface 106 of the second optical element 105. To this end, a light beam 110 from a light source 111 is captured after interaction with the optical measurement surface 106 of the second optical element 105 by way of a detector 112. The light source 111, the light beam 110 and the detector 112 form a measurement apparatus 113. The degradation value can be determined, depending on the measurement apparatus, as a reflectivity value, a polarization value or a phase value.

The polarization value is determined by ellipsometry. The optical measurement surface 106 of the second optical element 105 is irradiated with, for example, light with a predetermined polarization, for example linearly polarized light, from the light source 111, and the light reflected at the optical measurement surface 106 of the second optical element 105 is picked up by the detector 112. Afterwards, the polarization state of the reflected light is determined and a change in this polarization state in comparison with the predetermined polarization is examined. A degradation of the optical measurement surface 106 of the second optical element 105 can be determined on the basis of this change.

If the degradation value is a phase value, it may be determined interferometrically. To that end, for example, a specifiable reference interference pattern is compared with an interference pattern generated during the operation of the second optical element 105. A degradation of the optical measurement surface 106 of the second optical element 105 can be determined depending on the comparison, in particular depending on a determined deviation of the generated interference pattern from the reference interference pattern. For the interferometric determination, the mirror module illustrated in FIG. 1 preferably has an interferometer and a detector unit 112 for determining the interference patterns.

Likewise, FIG. 1 shows a purge unit 114. The purge unit 114 can be used to purge the interior space of the vacuum housing 102 with a purge gas of variable flow, preferably hydrogen. The purge unit 114 can be configured here such that it can convert the purge gas partially into charged species to produce, for example, in the case of hydrogen, activated hydrogen.

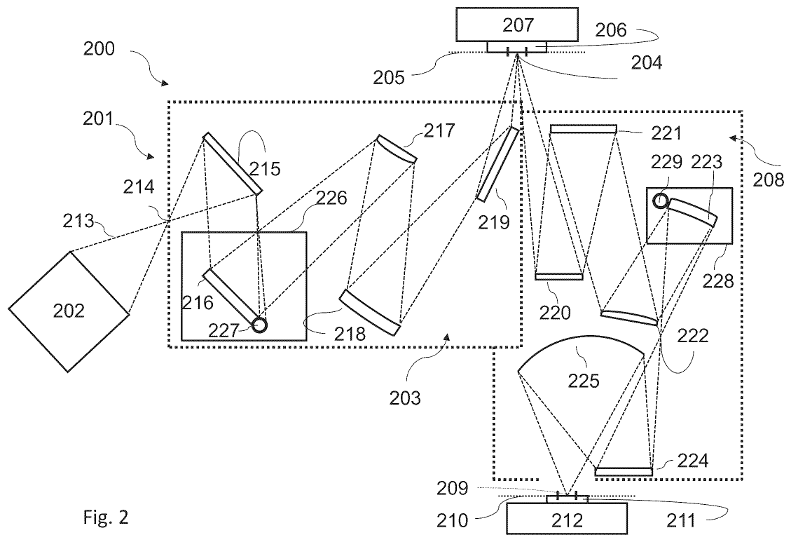

FIG. 2 shows by way of example the basic construction of an EUV projection exposure apparatus 200 for semiconductor lithography, in which the mirror module described in FIG. 1 is able to be employed.

An illumination system 201 of the projection exposure apparatus 200 has, besides a radiation source 202, an illumination optical unit 203 for the illumination of an object field 204 in an object plane 205. A reticle 206 arranged in the object field 204 is illuminated, said reticle being held by a reticle holder 207, a portion of which is illustrated schematically. A projection optical unit 208 serves for imaging the object field 204 into an image field 209 in an image plane 210. A structure on the reticle 206 is imaged onto a light-sensitive layer of a wafer 211 arranged in the region of the image field 209 in the image plane 210, said wafer being held by a wafer holder 212 that is likewise illustrated in part.

The radiation source 202 can emit EUV radiation 213. In specific examples, the EUV radiation 213 is in the range of between 5 nanometres and 30 nanometres, and in more specific examples, EUV radiation 213 has a wavelength of 13.5 nm. Optically differently designed and mechanically adjustable optical elements are used for controlling the radiation path of the EUV radiation 213. In the case of the EUV projection exposure apparatus 200 illustrated in FIG. 2, the optical elements are in the form of adjustable mirrors in suitable embodiments that are mentioned merely by way of example hereinafter. Individual optical elements in the form of mirrors can include a plurality of segments with mutually separate optical partial surfaces.

The EUV radiation 213 generated with the radiation source 202 is aligned via a collector mirror integrated in the radiation source 202 such that the EUV radiation 213 passes through an intermediate focus in the region of an intermediate focal plane 214 before the EUV radiation 213 is incident on a field facet mirror 215. Downstream of the field facet mirror 215, the EUV radiation 213 is reflected by a pupil facet mirror 216. With the aid of the pupil facet mirror 216 and further mirrors 217, 218, 219, field facets of the field facet mirror 215 are imaged into the object field 204. In this regard, see U.S. Pat. No. 9,411,241 B2 accordingly.

The reticle 206 arranged in the object field 204 can be, for example, a reflective photomask, which has reflective and non-reflective, or at least less reflective, regions for producing at least one structure on the reticle 206. Alternatively, the reticle 206 can be a plurality of micro-mirrors, which are arranged in a one-dimensional or multi-dimensional arrangement and which are optionally movable about at least one axis, in order to set the angle of incidence of the EUV radiation on the respective mirror.

The reticle 206 reflects some of the beam path of the illumination optical unit 203 and shapes a beam path in the projection optical unit 208 that sends information via the structure of the reticle into the projection optical unit 208, said information producing an image representation of the reticle or of a respective partial region thereof on the wafer 211 arranged in the image plane 210. The wafer comprises a semiconductor material, for example silicon, and is arranged on a wafer holder 212, which is also referred to as a wafer stage.

In the present example, the projection lens 208 has six reflective optical elements 220 to 225, which are in the form of mirrors, in order to generate an image of the reticle 206 on the wafer 211. The number of mirrors in a projection lens 208 is typically between four and eight. However, it is also possible to use more or fewer mirrors, such as only two mirrors or even ten mirrors. Projection lenses are known from US 2016/0327868 A1 and DE 102018207277 A1.

The radiation source 202 with the collector mirror, the optical elements 215 to 219 of the illumination optical unit 203 and the optical elements 220 to 225 of the projection optical unit 208 are typically arranged in a separate vacuum environment.

By way of example, FIG. 2 illustrates such a vacuum housing 226, in which the optical element of the illumination optical unit 203 that comes second in the light direction, the pupil facet mirror 216, is arranged. Furthermore, a second optical element 227 within the meaning of the application is illustrated within the vacuum housing 226 of the pupil facet mirror 216 as a first optical element within the meaning of the application with an optical used surface. This second optical element 227 comprises an optical measurement surface and has an identical construction of the reflective optical layer compared to the optical used surface of the pupil facet mirror 216. The second optical element 227 with the optical measurement surface is located, like the pupil facet mirror 216, in the beam path of the EUV radiation 213 after its reflection at the field facet mirror 215. The vacuum housing 226, the interior space enclosed by it and the optical elements 216, 227 contained therein are understood here to be a mirror module according to FIG. 1. By arranging the second optical element 227 in the immediate vicinity of the pupil facet mirror 216 within the mirror module formed by the vacuum housing 226, the same residual gas atmosphere, including any oxidizing species, acts on both optical elements. In this way, it is possible by describing or examining a degradation value of the optical measurement surface of the second optical element 227 to directly draw conclusions regarding a degradation of the optical used surface of the pupil facet mirror 216.

FIG. 2 shows, by way of example, for the projection optical unit a second vacuum housing 228 for enclosing the fourth optical element 223 according to the beam path of the projection optical unit 208. The optical element 223 likewise has a second optical element 229 within the meaning of the application for determining a degradation state of the optical element 223 within the second vacuum housing 228.

Typically, a plurality of the optical elements 215 to 219, 220 to 225 and the reticle 206 are arranged in a respective vacuum housing and in this way are configured as a mirror module. In each case two successive mirror modules in the beam path are connected here to each other such that the beam path can pass through the common opening.

As also illustrated in FIG. 1, there is a purge gas connection at each of the mirror modules formed by the vacuum housings 226, 228, with which connection a purge gas can be injected into the interior space of the vacuum housings 226, 228, and ideally in each case a residual gas analyser to determine the composition of the residual gas atmosphere. Also located within the vacuum housings 226, 228 is a measurement apparatus for monitoring the optical surface of the respectively second optical element. These components are not depicted for reasons of clarity.

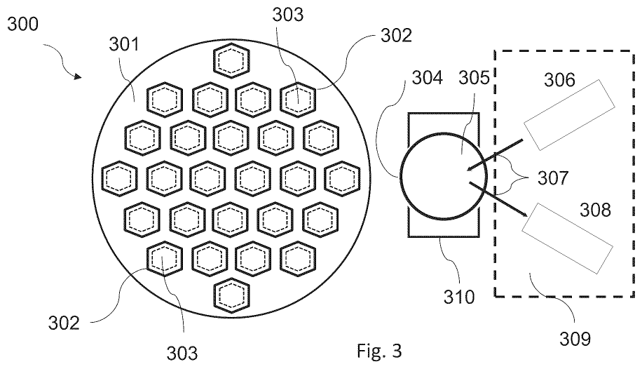

According to one exemplary embodiment, FIG. 3 shows a schematic plan view of a mirror module 300, a first optical element 301 that includes a plurality of used facets 302 with an optical used surface 303, and at least one second optical element 304 with an optical measurement surface 305. Both optical elements are located, as described in FIG. 2, together in a separated vacuum environment, which is monitorable by a residual gas analyser. The separated vacuum environment and the residual gas analyser are not illustrated in FIG. 3. The second optical element 304 is separated from the first optical element 301. It should be understood that the construction of the first optical element 301 and of the optical used surface 303 of the plurality of used facets 302 can also be embodied as a closed surface. In this exemplary embodiment, too, there is the possibility that the temperatures of the first optical element 301 and the second optical element 304 are controlled separately for a selective temperature setting. The temperatures of the used facets 302 of the first optical element 301 can here be controlled individually. Likewise, the first optical element 301 can have a different, in particular lower, heat capacity than the second optical element 304. In this way, with a comparable introduction of heat, a temperature T1 of the second optical element 304 is established, which differs from, in particular is lower than, a temperature T2 of the first optical element 301.

In order to determine a degradation value of the optical measurement surface 305 of the second optical element 304, a light source unit 306 is arranged in a manner such that it directs specifically structured light 307 at the optical measurement surface 305 of the second optical element 304. After it has interacted with the optical measurement surface 305, the structured light 307 is collected again by a detector unit 308. A change in the optical signal that is registered in the detector unit 308, compared with a reference signal, is used to determine the measure of the degradation of the optical measurement surface 305. The light source unit 306, the structured light 307 and the detector unit 308 form an example measurement apparatus 309 for determining the degradation value of the optical measurement surface 305. As has already been described, the degradation value can be determined as a reflectivity value, as a phase value or as a polarization value.

The exemplary embodiment shown in FIG. 3 illustrates the second optical element 304 including the measurement apparatus 309 for the early detection of any potential degradation of the optical used surface 303. In order to potentially counteract different ambient conditions, such as the power of the EUV radiation or the residual gas atmosphere in the region of the first optical element 301, it is likewise possible that further second optical elements 304 are arranged separated from the first optical element 301 and are addressed by a plurality of measurement apparatuses. For this purpose, it is also possible that the further second optical elements 304 are controlled to different temperatures T1. This is useful especially in the case of larger optical elements with possibly greater variations in the ambient conditions.

A further feature of the mirror module 300 shown in FIG. 3 is the exchangeability of the second optical element 304. Since the second optical element 304 is operated under conditions that foster a degradation of the optical measurement surface 305 in comparison with the optical used surface 303 of the first optical element 301 that is to be monitored, the risk of an irreversible change in the optical measurement surface 305 is correspondingly higher. In this case, the overall performance of the first optical element 301 is acceptable, while the irreversible change in the optical measurement surface 305 of the second optical element 304 no longer allows the use, as described above, for early detection of a degradation. It is advantageous here if the second optical element 304 is arranged exchangeably. For this purpose, the second optical element 304 is attached on a holding apparatus 310. This holding apparatus 310 can be transferred out of the respective region during operation pauses of the projection exposure apparatus and the attachment to the second optical element 304 can be released. Subsequently, a new, second optical element 304 with an intact optical measurement surface 305 can be positioned and attached on the holding apparatus 310. This new, second optical element 304 is attached to the holding apparatus 310 and then transferred into the region of the first optical element 301. It is likewise possible to design the holding apparatus 310 to be laterally displaceable, so that a region of the optical measurement surface 305 that is not yet degraded can be brought into the irradiation and measurement position. It is likewise possible to displace an irradiation spot on the optical measurement surface 305 within a measurement window of the measurement apparatus 309 by correspondingly adapting the orientation of the assigned measurement facet in a facet module.

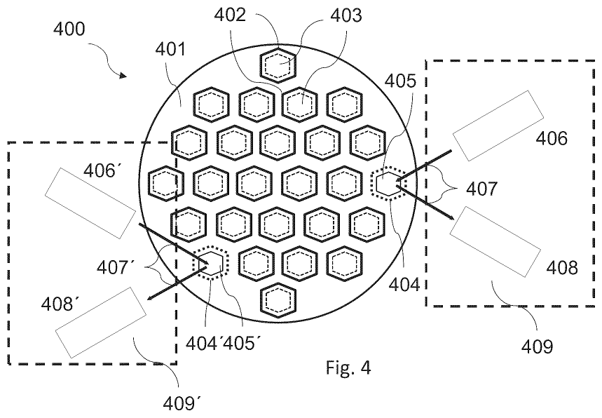

According to a further exemplary embodiment, the mirror module 400 illustrated in FIG. 4 is shown. The optical element 401 includes a plurality of facets. The facets are configured as used facets 402 with an optical used surface 403 or as measurement facets 404 with an optical measurement surface 405. The used facets in this case form the first optical element according to the disclosed techniques and the measurement facets form the second optical element according to the disclosed techniques.

It may be advantageous, particularly for a projection lens, if the measurement surface 405 is part of the used surface 403.

The monitoring of the optical used surface 403 of the used facets 402 as an integral part of the mirror module 400 is ensured in this example by at least one individual measurement facet 404 of the optical element 401. For this exemplary embodiment, temperature control of the at least one measurement facet 404 to a temperature T1 and of the used facets 402 to a temperature T2 is provided in a manner such that a temperature control apparatus comprises a first temperature control unit for the temperature control of the at least one measurement facet 404 with the optical measurement surface 405 and a second temperature control unit for the temperature control of the used facet 402 with the optical used surface 403. In this case, a temperature T1 of the at least one measurement facet 404 is set, which is lower than the temperature T2 of the used facets 402. In this way, a degradation of the optical measurement surface 405 is fostered in comparison with the optical used surface 403. For this purpose, the at least one measurement facet 404 can likewise have a heat capacity that is different from, in particular smaller than, the used facets 402. In this way, with a comparable introduction of heat, a temperature T1 of the at least one measurement facet 404 is established, which differs from, in particular is lower than, a temperature T2 of the used facets 402.

In order to determine a degradation value of the optical measurement surface 405 of the at least one measurement facet 404, at least one light source unit 406 is arranged in a manner such that it directs specifically structured light 407 at the optical measurement surface 405 of the measurement facet 404. After it has interacted with the optical measurement surface 405, the structured light 407 is collected again by a detector unit 408. A change in the optical signal that is registered in the detector unit 408, compared with a reference signal, is used to determine or measure the degradation of the optical measurement surface 405. The light source unit 406, the structured light 407 and the detector unit 408 form in this case a measurement apparatus 409 for determining the degradation value of the optical measurement surface 405. As has already been described, the degradation value can be determined as a reflectivity value, as a phase value or as a polarization value. In this configuration, the measurement apparatus 409 monitors, for example, a most critical part of the used surface 403, that is to say the part having the highest expected degradation rate.

In the exemplary embodiment shown in FIG. 4, a second facet of the optical element 401 is configured as a measurement facet 404′ with an optical measurement surface 405′. This second measurement facet 404′ is likewise assigned a measurement apparatus 409′ comprising a light source unit 406′, structured light 407′ and a detector unit 408′. In this way, different regions of the optical element 401 can be monitored in parallel with the aim of avoiding the degradation of the optical used surface 403. If one of the measurement facets fails as a consequence of irreversible degradation, the possibility of monitoring using the further measurement facets and the assigned measurement apparatuses is additionally ensured. The number of the measurement facets and the assigned measurement apparatuses is not limited here. In this exemplary embodiment, too, it is possible that the plurality of measurement facets (404, 404′) are controlled to different temperatures T1 in order to enable, for example for regions having a different power of the EUV radiation, a respectively adapted sensitivity of the degradation detection. It should be understood that the statements made regarding the passive setting of the temperature by way of different heat capacities are also transferable to the second measurement facet 404′.

One advantage of the embodiment illustrated in FIG. 4 is the lower material outlay because a separated, second optical element including an apparatus for holding can be omitted. This is useful in regions with strict installation space restrictions within a mirror module of a projection exposure apparatus.

Furthermore, reference is made in the case of the mirror module illustrated in FIG. 4 to the possibility that the optical surfaces (403, 405, 405′) of the optical element 401 are not necessarily composed of individual facets (402, 404, 404′). It is likewise possible for a closed optical surface to be formed, which is divided locally into an optical used surface and an optical measurement surface with an assigned measurement apparatus.

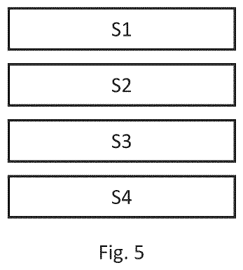

FIG. 5 shows a flowchart providing a generalized process flow of a method according to the disclosed techniques for avoiding a degradation of an optical used surface of a mirror module for a projection exposure apparatus according to the previous exemplary embodiments. The method will be described with reference to the illustrated optical elements (103, 105, 301, 304, 401, 404, 404′). The method in FIG. 5 is applicable to the optical elements 215-219 and 220-225 within a projection exposure apparatus, which are shown in FIG. 2.

In a first step S1, a degradation value of the optical measurement surface (106, 305, 405, 405′) of the mirror module (100, 300, 400) is determined. As has already been described, the degradation value is determined as a reflectivity value, as a phase value or as a polarization value. Accordingly, for this purpose, structured light (307, 407, 407′) interacts with the optical measurement surface (106, 305, 405, 405′).

In a second step S2, a temperature difference between the optical measurement surface (106, 305, 405, 405′) and the optical used surface (104, 303, 403) is set such that the temperature T1 of the optical measurement surface (106, 305, 405, 405′) is lower than the temperature T2 of the optical used surface (104, 303, 403).

Preferably, a temperature difference of at least 0.5 K, preferably 1 K, and with particular preference 2 K, is set here.

In a third step S3, preferably at least one measure for reducing the degradation is initiated when the determined degradation value reaches a limit degradation value.

In a fourth step S4, the at least one measure performed is preferably increasing the temperature T1 of the optical measurement surface and/or the temperature T2 of the optical used surface.

In a fourth step S4, the at least one measure performed is preferably a change in a purge gas atmosphere.

In a fourth step S4, the at least one measure performed is preferably a partial or complete reduction in the power of EUV radiation used for imaging.

In a fourth step S4, the at least one measure performed is preferably a reduction of one or more concentrations of oxidizing species.

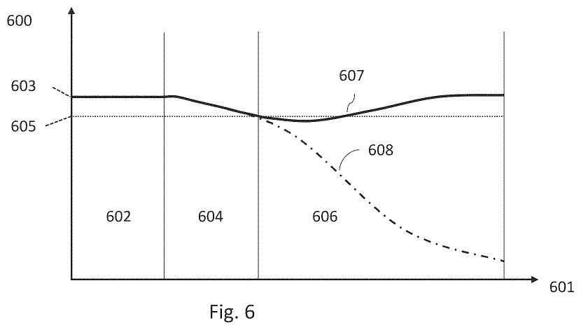

FIG. 6 shows a possible profile of the degradation value 600 of an optical measurement surface as an integral part of a mirror module of a projection exposure apparatus as a function of an operating duration 601 according to the described method. The degradation value 600 is an optical signal here and can be determined, depending on the measurement method used, as a reflectivity value, as a phase value or as a polarization value.

In a first operating phase 602, effectively no change in the degradation value 600 of the optical measurement surface is determined. The degradation value remains within the region of an original degradation value 603. It follows that the operating conditions present during the first operating phase 602 in the region of the optical measurement surface and also of the optical used surface to be monitored do not foster degradation.

In a second operating phase 604, the degradation value 600 of the optical measurement surface slightly changes or decreases compared with the original degradation value 603 of the first operating phase 602 in the direction of a limit degradation value 605. It follows that the operating conditions present during the second operating phase 604 in the region of the optical measurement surface and also of the optical used surface to be monitored foster degradation. For example, the power of the EUV radiation during the transition of the operating phases 602 to 604 may have been increased. It is likewise possible that a thermally induced dynamic of the outgassing behaviour of one or more oxidizing species has occurred, as a result of which the concentration thereof in the region of the optical measurement surface and of the optical used surface has increased. It is just as possible for an air or water leakage within the projection exposure apparatus to have occurred, as a result of which the concentration of oxidizing species in the region of the optical measurement surface and of the optical used surface has increased.

As a consequence of reaching the limit degradation value 605 during a transition from the second operating phase 604 to a third operating phase 606, various measures which have already been described individually can be taken. In this case, the degradation value of the optical measurement surface follows a first possible profile 607 during the third operating phase 606. A change in the degradation value 600 in this case proceeds in the direction of the original degradation value 603. If the degradation process from the second operating phase 604 is of an exclusively reversible nature, the original degradation value 603 of the optical measurement surface is in that case reached again and it will be fully available in this case for further monitoring according to the method according to the disclosed techniques.

If no measures are taken, or are not taken in time, at the beginning and/or during the third operating phase 606 after the limit degradation value 605 has been reached, the degradation value 600 follows a second possible profile 608. A change in the degradation value 600 in this case follows the tendency of the change in the degradation value 600 during the second operating phase 604. However, this progressive change in the degradation value 600 during the third operating phase 606 is significantly more pronounced. It follows that the degradation of the optical measurement surface that began during the second operating phase 604 continues with an irreversible character as a consequence of critical operating conditions. In this case, the optical measurement surface or at least the measurement region used can no longer be used for monitoring the optical used surface, since the surfaces of the two regions no longer have a comparable composition.

### LIST OF REFERENCE SIGNS

100 Mirror module
101 Imaging radiation
102 Vacuum housing
103 First optical element
104 Optical used surface
105 Second optical element
106 Optical measurement surface
107 Residual gas analyser
108 First temperature control unit
109 Second temperature control unit
110 Light beam
111 Light source
112 Detector
113 Measurement apparatus
114 Purge unit
200 Projection exposure apparatus
201 Illumination system
202 Radiation source
203 Illumination optical unit
204 Object field
205 Object plane
206 Reticle
207 Reticle holder
208 Projection optical unit
209 Image field
210 Image plane
211 Wafer
212 Wafer holder
213 EUV radiation
214 Intermediate focal plane
215 Field facet mirror
216 Pupil facet mirror
217-219 Further mirrors of the illumination optical unit
220-225 Further optical elements of the projection optical unit
226 Vacuum housing
227 Second optical element
228 Vacuum housing
229 Second optical element
300 Mirror module
301 First optical element
302 Used facet
303 Optical used surface
304 Second optical element
305 Optical measurement surface
306 Light source unit
307 Structured light
308 Detector unit
309 Measurement apparatus
310 Holding apparatus
400 Mirror module
401 Optical element
402 Used facet
403 Optical used surface
404, 404′ Second optical element
405, 405′ Optical measurement surface
406, 406′ Light source unit
407, 407′ Structured light
408, 408′ Detector unit
409, 409′ Measurement apparatus
S1 First method step
S2 Second method step
S3 Third method step
S4 Fourth method step
600 Degradation value
601 Operating duration
602 First operating phase
603 Original degradation value
604 Second operating phase
605 Limit degradation value
606 Third operating phase
607 First possible profile
608 Second possible profile

What is claimed is:

1. A mirror module for a projection exposure apparatus, comprising:
an optical used surface,
an optical measurement surface,
a measurement device configured to determine a degradation state of the optical measurement surface, and
a temperature controller configured set a temperature of the optical measurement surface lower than a temperature of the optical used surface.

2. The mirror module of claim 1, wherein the temperature of the optical measurement surface is at least 0.5 K lower than the temperature of the optical used surface.

3. The mirror module of claim 1, wherein the mirror module comprises at least one first optical element with the optical used surface and at least one second optical element with the optical measurement surface.

4. The mirror module of claim 3, wherein the temperature controller is configured for passively setting a temperature T1 of the optical measurement surface differently, in particular lower, compared with a temperature T2 of the optical used surface owing to different heat capacities of the at least one first optical element and of the at least one second optical element.

5. The mirror module of claim 3, wherein the at least one second optical element is arranged separated from the at least one first optical element.

6. The mirror module of claim 3, wherein the at least one second optical element is exchangeable.

7. The mirror module of claim 3, wherein the at least one first optical element comprises a plurality of used facets.

8. The mirror module of claim 3, wherein the at least one second optical element comprises a plurality of measurement facets.

9. The mirror module of claim 8, wherein each measurement facet is assigned a separate measurement apparatus.

10. The mirror module of claim 8, wherein the temperature controller is configured to set different temperatures on different measurement facets.

11. The mirror module of claim 10, wherein the temperature controller comprises at least one first temperature controller configured to set a first temperature T1 of the optical measurement surface.

12. The mirror module of claim 11, wherein the temperature controller comprises at least one second temperature controller configured to set a second temperature T2 of the optical used surface.

13. The mirror module of claim 12, wherein the at least one first temperature controller and/or the at least one second temperature controller is designed as a fluid heater, Peltier element, radiant heater or electrical resistance heater.

14. The mirror module of claim 1, wherein the measurement device is configured such that it determines the degradation state based on a reflectivity value, phase value or polarization value.

15. An illumination system for a projection exposure apparatus, comprising a mirror module according to claim 1.

16. A projection lens for a projection exposure apparatus, comprising a mirror module according to claim 1.

17. A projection exposure apparatus comprising an illumination system according to claim 15.

18. A projection exposure apparatus comprising a projection lens according to claim 16.

19. A method for avoiding a degradation of an optical used surface of a mirror module for a projection exposure apparatus, wherein a degradation value of an optical measurement surface of the mirror module is determined, the method comprising:
setting a temperature difference between the optical measurement surface and the optical used surface such that a temperature of the optical measurement surface is lower than a temperature of the optical used surface; and
determining the degradation value of the optical measurement surface based on a change in optical properties of the optical measurement surface.

20. The method of claim 19, wherein setting the temperature difference comprises setting a temperature difference of at least 0.5 K.

21. The method of claim 19, further comprising performing at least one measure for reducing the degradation of the optical used surface when the determined degradation value deviates from threshold degradation value.

22. The method of claim 21, wherein the at least one measure performed comprises one or more of an increase in the temperature of the optical measurement surface and/or T2 of the optical used surface; a change in a purge gas atmosphere; or a partial or complete reduction in a power of EUV radiation used for imaging.
